(19) United States
(12) Patent Application Publication
(10) Pub. No.: US 2025/0222551 A1
(43) Pub. Date: Jul. 10, 2025

(54) PROCESSING METHOD FOR BOULE AND GRINDING EQUIPMENT

(71) Applicant: GlobalWafers Co., Ltd., Hsinchu (TW)

(72) Inventor: Ching-Shan Lin, Hsinchu (TW)

(73) Assignee: GlobalWafers Co., Ltd., Hsinchu (TW)

(21) Appl. No.: 18/928,192

(22) Filed: Oct. 28, 2024

Related U.S. Application Data
(60) Provisional application No. 63/619,316, filed on Jan. 10, 2024.

(51) Int. Cl. B24B 5/50

(52) U.S. Cl. CPC B24B 5/50

(57) ABSTRACT

A processing method for a boule includes the following steps. The boule is moved to a first processing station of a grinding equipment, and a first grinding wheel located within the first processing station is utilized to perform a sidewall grinding process on a sidewall of the boule. During the sidewall grinding process, the boule rotates along a first rotational axis, and the first grinding wheel rotates along a second rotational axis, wherein the first rotational axis is parallel to the second rotational axis. The boule is moved to a second processing station of the grinding equipment, and a second grinding wheel located within the second processing station is utilized to perform a top surface grinding process on a top surface of the boule.

### CROSS-REFERENCE TO RELATED APPLICATION

This application claims the priority benefit of U.S. application Ser. No. 63/619,316, filed on Jan. 10, 2024. The entirety of the above-mentioned patent application is hereby incorporated by reference herein and made a part of this specification.

### BACKGROUND

### Technical Field

The present invention relates to a processing method for a boule and a grinding equipment.

### Description of Related Art

Wafers are critical materials in the production of various integrated chips. The general process for manufacturing wafers typically encompasses the following steps. Initially, a boule is formed within a crystal growth furnace. Subsequently, the boule is extracted from the growth furnace. Thereafter, the head and tail portions of the boule are removed. These portions are typically excised due to irregularities or defects resulting from fluctuations during the growth process. Finally, a slicing procedure is executed to obtain multiple wafers. Each individual wafer must possess a high degree of planarity and uniformity to accommodate subsequent semiconductor manufacturing processes.

In order to enhance wafer yield and ensure the integrity of the boule during processing, numerous manufacturing facilities are actively developing new technologies to mitigate the risk of fissures in the boule during the fabrication process. Furthermore, they are focusing on optimizing processing time to improve overall production efficiency. These technological advancements not only serve to elevate wafer quality but also contribute to the reduction of manufacturing costs, thereby enhancing competitive advantage.

### SUMMARY

The present invention provides a processing method for a boule, which may improve the problem of cracks in the boule during the grinding process and improve the processing efficiency of the boule.

The present invention provides a grinding equipment that may reduce the problem of cracks in the object being ground during the grinding process.

At least one embodiment of the present invention provides a processing method for a boule, and the method includes the following steps. The boule is moved to a first processing station of a grinding equipment, and a first grinding wheel located within the first processing station is utilized to perform a sidewall grinding process on a sidewall of the boule. During the sidewall grinding process, the boule rotates along a first rotational axis, and the first grinding wheel rotates along a second rotational axis, wherein the first rotational axis is parallel to the second rotational axis, and the direction in which the boule rotates along the first rotational axis is equal to the direction in which the first grinding wheel rotates along the second rotational axis. The boule is moved to a second processing station of the grinding equipment, and a second grinding wheel located within the second processing station is utilized to perform a top surface grinding process on a top surface of the boule. During the top surface grinding process, the second grinding wheel rotates along a third rotational axis, and the boule rotates along the first rotational axis, wherein the third rotational axis is perpendicular to the first rotational axis.

At least one embodiment of the present invention provides a grinding equipment, which includes a movable carrier module, a first grinding module and a second grinding module. The movable carrier module includes a processing platform and a platform rotating motor. The processing platform is configured to move between the first processing station and the second processing station. The platform rotating motor is configured to rotate the processing platform along a first rotational axis. The first grinding module includes a first grinding wheel. The first grinding wheel is located within the first processing station and is configured to move up and down along the z-axis and is configured to rotate along the second rotational axis. The second rotational axis is parallel to the first rotational axis. The second grinding module includes a second grinding wheel. The second grinding wheel is located within the second processing station and is configured to move up and down along the z-axis and is configured to rotate along the third rotational axis. The third rotational axis is perpendicular to the first rotational axis.

### BRIEF DESCRIPTION OF THE DRAWINGS

FIG. 1 is a schematic diagram of a grinding equipment according to an embodiment of the present invention.

FIG. 2A and FIG. 2B are schematic diagrams of a processing method for a boule according to an embodiment of the present invention.

FIG. 3 is a flow chart of a processing method for a boule according to an embodiment of the present invention.

FIG. 4A is a schematic diagram of a method of forming a flat on the sidewall of a boule according to an embodiment of the present invention.

FIG. 4B is a flow chart of a method of forming a flat on the sidewall of a boule according to an embodiment of the present invention.

FIG. 5A is a schematic diagram of a method of forming a notch on the sidewall of a boule according to an embodiment of the present invention.

FIG. 5B is a flow chart of a method of forming a notch on the sidewall of a boule according to an embodiment of the present invention.

FIG. 6A is a schematic diagram of a grinding equipment and a method of using the grinding equipment to form a flat on the sidewall of a boule according to an embodiment of the present invention.

FIG. 6B is a partial enlarged view of FIG. 6A.

FIG. 7A is a schematic diagram of a grinding equipment and a method of using the grinding equipment to form a notch on the sidewall of a boule according to an embodiment of the present invention.

FIG. 7B is a partial enlarged view of FIG. 7A.

### DESCRIPTION OF THE EMBODIMENTS

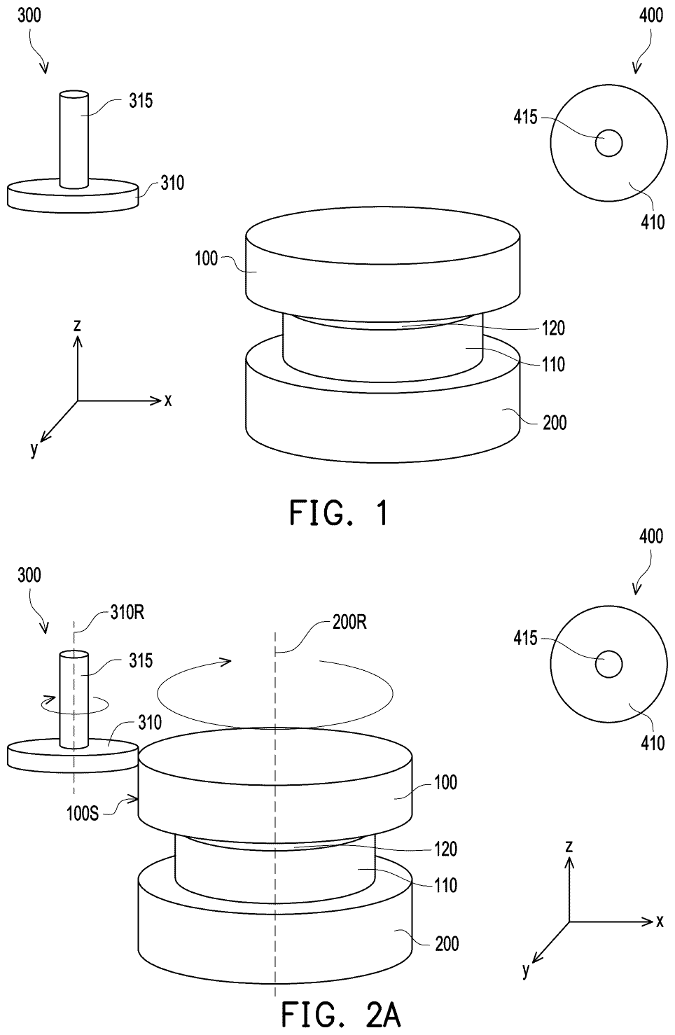

FIG. 1 is a schematic diagram of a grinding equipment according to an embodiment of the present invention. Please refer to FIG. 1, the grinding equipment includes a movable carrier module 200, a first grinding module 300 and a second grinding module 400.

The boule 100 is fixed on the movable carrier module 200. For example, the boule 100 is attached to the magnetic object 110 through the adhesive layer 120. In some embodiments, the adhesive layer 120 includes wax or other suitable materials. For example, liquid wax is applied to the magnetic object 110 or the boule 100, and then the boule 100 is attached to the magnetic object 110. After the wax solidifies, the boule 100 is fixed on the magnetic object 110. In some embodiments, the magnetic object 110 includes iron, steel, nickel, cobalt, or other materials that can be attracted to magnets. In some embodiments, the magnetic object 110 overlaps the center of the boule 100, and the boule 100 is fixed on the movable carrier module 200 through the magnetic object 110. For example, permanent magnets or electromagnets in the movable carrier module 200 may be used to attract the magnetic object 110.

The movable carrier module 200 is utilized to move the boule 100 along the x-axis. In some embodiments, the movable carrier module 200 is able to move the boule 100 along the y-axis in addition to moving the boule 100 along the x-axis. In FIG. 1, the x-axis, y-axis, and z-axis are perpendicular to each other.

The first grinding module 300 includes a first grinding wheel 310 and a vertical main axis 315 connected to the first grinding wheel 310. The first grinding wheel 310 is located in the first processing station and is configured to move up and down along the z-axis. In some embodiments, the first grinding module 300 further includes a first servo motor (not shown in FIG. 1). The first servo motor is configured to control the rotation of the first grinding wheel 310 and the vertical main axis 315.

The second grinding module 400 includes a second grinding wheel 410 and a horizontal main axis 415 connected to the second grinding wheel 410. The second grinding wheel 410 is located in the second processing station. The second grinding wheel 410 is configured to move up and down along the z-axis. In some embodiments, the second grinding module 400 further includes a second servo motor (not shown in FIG. 1). The second servo motor is configured to control the rotation of the second grinding wheel 410 and the horizontal main axis 415.

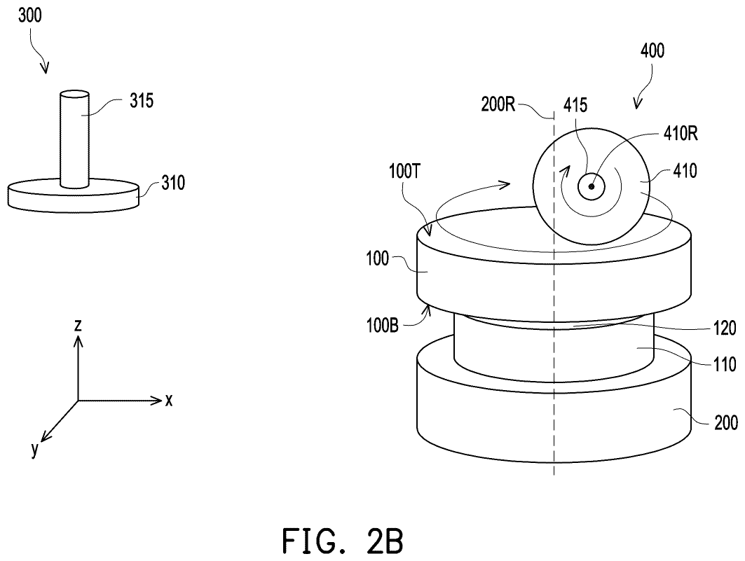

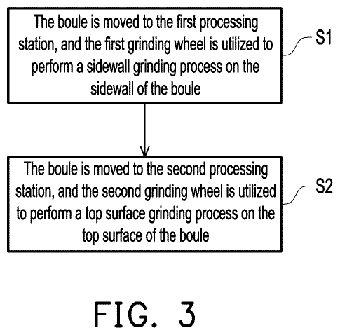

FIG. 2A and FIG. 2B are schematic diagrams of a processing method for a boule according to an embodiment of the present invention. FIG. 3 is a flow chart of a processing method for a boule according to an embodiment of the present invention. Referring to FIG. 2A and step S1 in FIG. 3, the boule 100 is moved to the first processing station (the left part of FIG. 2A), and the first grinding wheel 310 is utilized to perform a sidewall grinding process on the sidewall 100S of the boule 100.

During the sidewall grinding process, the boule 100 rotates clockwise or counterclockwise along the first rotational axis 200R, and the first grinding wheel 310 rotates clockwise or counterclockwise along the second rotational axis 310R. The first rotational axis 200R is parallel to the second rotational axis 310R, thereby reducing the probability of cracks in the boule caused by the sidewall grinding process. In some embodiments, both the first rotational axis 200R and the second rotational axis 310R are parallel to the z-axis.

In some embodiments, during the sidewall grinding process, the direction in which the boule 100 rotates along the first rotational axis 200R is equal to the direction in which the first grinding wheel 310 rotates along the second rotational axis 310R, thereby obtaining higher grinding efficiency. For example, both are rotated clockwise or both are rotated counterclockwise.

In some embodiments, the thickness of the first grinding wheel 310 in the z-axis direction is less than the thickness of the boule 100 in the z-axis direction. Therefore, during the sidewall grinding process, the first grinding wheel 310 moves along the z-axis. Specifically, the first grinding wheel 310 moves up and down along the z-axis, so that the entire sidewall 100S of the boule 100 may be brought into contact with the first grinding wheel 310 in the thickness direction (i.e., the direction of the z-axis). In addition, during the sidewall grinding process, the boule 100 moves toward the first grinding wheel 310 along the x-axis and/or the y-axis perpendicular to the z-axis to grind away the uneven portion of the sidewall 100S of the boule 100.

After grinding the sidewall 100S of the boule 100 into a smooth surface, the boule 100 is substantially circular in top view.

In some embodiments, before performing the sidewall grinding process, an X-ray instrument (not shown) is optionally utilized to perform a first crystal plane measurement procedure on the boule 100 to roughly estimate the crystal plane orientation of the boule 100.

Next, please refer to FIG. 2B and step S2 in FIG. 3, the boule 100 is moved to the second processing station (the right part of FIG. 2B). For example, the movable carrier module 200 moves along the x-axis and/or the y-axis, and moves the boule 100 located thereon to the second processing station. Next, the second grinding wheel 410 in the second processing station is utilized to perform a top surface grinding process on the top surface 100T of the boule 100.

In the top surface grinding process, the boule 100 rotates clockwise or counterclockwise along the first rotational axis 200R, and the second grinding wheel 410 rotates clockwise or counterclockwise along the third rotational axis 410R. In some embodiments, the third rotational axis 410R is perpendicular to the first rotational axis 410R. In some embodiments, the third rotational axis 410R is parallel to the y-axis.

Compared with using the cutting method to remove the uneven top surface of boule 100, this embodiment utilizes the second grinding wheel 410 to grind the top surface 100T, which not only is able to effectively reduce the loss of material, but also make the processed top surface 100T have lower roughness.

During the top surface grinding process, the second grinding wheel 410 moves toward the top surface 100T of the boule 100 along the z-axis, so that the second grinding wheel 410 contacts the top surface 100T of the boule 100. In addition, during the top surface grinding process, the boule 100 moves along the x-axis and/or the y-axis perpendicular to the z-axis, so that the entire top surface 100T of the boule 100 may be brought into contact with the second grinding wheel 410 to grind the uneven portion on the top surface 100T of the boule 100.

In some embodiments, the second grinding wheel 410 first contacts the peripheral portion of the top surface 100T, and then the boule 100 is moved to move the second grinding wheel 410 from the periphery of the top surface 100T to the center of the top surface 100T until the entire top surface 100T of the boule 100 are all ground by the second grinding wheel 410.

In some embodiments, after performing the top surface grinding process, the boule 100, the magnetic object 110 and the adhesive layer 120 are removed from the movable carrier module 200, and then the boule 100 is picked up from the adhesive layer 120. Thereafter, the boule 100 is turned over so that the ground top surface 100T is attached to the magnetic object 110 using another adhesive layer, while the unground bottom surface 100B of the boule 100 faces upward. Then the boule 100 is re-fixed on the movable carrier module 200 using the magnetic object 110, and the boule 100 is moved to the second processing station. The bottom surface 100B of the boule 100 is ground using the same processing method as shown in FIG. 2B to obtain an ingot. After the ingot is obtained, the ingot is removed and cut to obtain multiple wafers.

In some embodiments, before performing the top surface grinding process, a flat or a notch is optionally formed on the sidewall 100S of the boule 100. Specifically, after performing the sidewall grinding process and before performing the top surface grinding process, an X-ray instrument (not shown) is utilized to perform a second crystal plane measurement procedure on the boule 100, and the position (or processing region) of the flat or notch to be formed on the sidewall 100S of the boule 100 is obtained. Next, the first grinding module 300 is utilized to form a flat in the aforementioned processing region or the second grinding module 400 is utilized to form a notch in the aforementioned processing region. In some embodiments, the boule 100 is removed from the movable carrier module 200 and moved to an X-ray instrument for the second crystal plane measurement procedure.

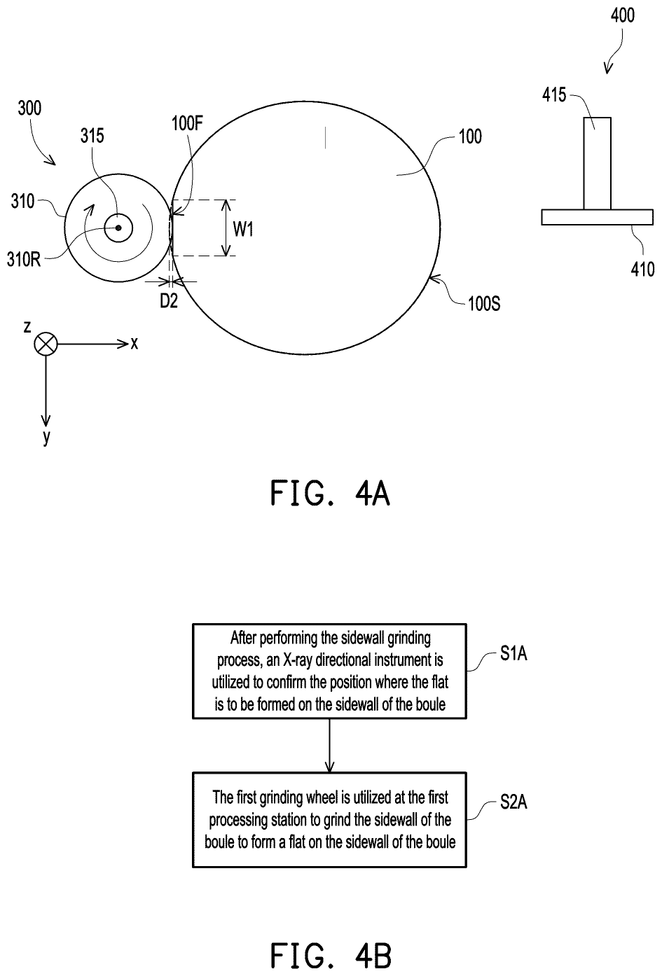

The method of forming a flat on the sidewall 100S of the boule 100 will be described below with reference to FIG. 4A and FIG. 4B. In step S1A of FIG. 4B, after performing the sidewall grinding process, an X-ray directional instrument is utilized to confirm the position (or processing region) where the flat is to be formed on the sidewall 100S of the boule 100.

Next, please refer to FIG. 4A and step S2A in FIG. 4B, the boule 100 is repositioned on the movable carrier module 200, and the movable carrier module 200 is utilized to move the boule 100 to the first processing station. The first grinding wheel 310 is utilized to form a flat 100F on the processing region of the sidewall 100S. During the process of forming the flat 100F, the first grinding wheel 310 rotates clockwise or counterclockwise along the second rotational axis 310R. During the process of forming the flat 100F, the first grinding wheel 310 moves along the z-axis, and the boule 100 moves along the x-axis and/or the y-axis. In some embodiments, the boule 100 does not rotate during the formation of the flat 100F.

In some embodiments, the flat 100F has a depth D1 and a width W1.

In some embodiments, after forming the flat 100F, a top surface grinding process as shown in FIG. 2B is performed.

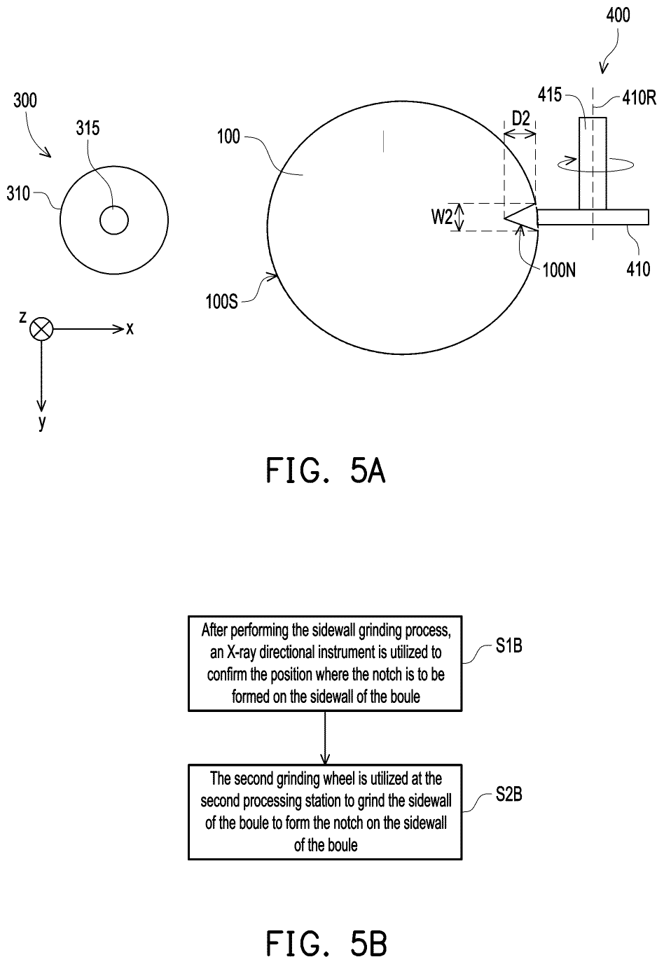

In other embodiments, the flat 100F is not formed on the sidewall 100S of the boule 100. Instead, a V-shaped notch 100N is formed on the sidewall 100S of the boule 100. The method of forming the notch 100N on the sidewall 100S of the boule 100 will be described below with reference to FIG. 5A and FIG. 5B. In step S1B of FIG. 4B, after performing the sidewall grinding process, an X-ray directional instrument is utilized to confirm the position (or processing region) where the notch is to be formed on the sidewall 100S of the boule 100.

Next, please refer to FIG. 5A and step S2B of FIG. 5B, the boule 100 is repositioned on the movable carrier module 200, and the movable carrier module 200 is utilized to move the boule 100 to the second processing station. The second grinding wheel 410 is utilized to form a notch 100N on the processing region of the sidewall 100S. During the process of forming the notch 100N, the second grinding wheel 410 rotates clockwise or counterclockwise along the third rotational axis 410R. During the process of forming the notch 100N, the second grinding wheel 410 moves along the z-axis, and the boule 100 moves along the x-axis and/or the y-axis.

In some embodiments, the notch 100N has a depth D2 and a width W2.

In some embodiments, after forming the notch 100N, a top surface grinding process as shown in FIG. 2B is performed.

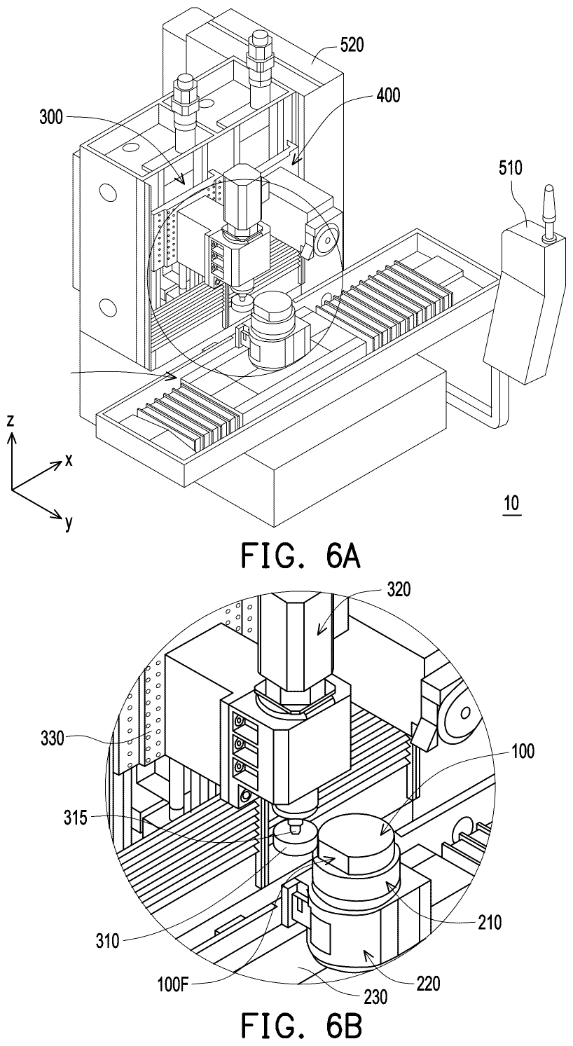

FIG. 6A is a schematic diagram of a grinding equipment and a method of using the grinding equipment to form a flat on the sidewall of a boule according to an embodiment of the present invention. FIG. 6B is a partial enlarged view of FIG. 6A. Referring to FIG. 6A and FIG. 6B, the grinding equipment 10 includes a movable carrier module 200, a first grinding module 300 and a second grinding module 400. In some embodiments, the grinding equipment further includes a control panel 510 and an electrical box 520.

In this embodiment, the boule 100 is moved to the first processing station, and the first grinding module 300 is utilized to form a flat 100F on the sidewall of the boule 100.

The movable carrier module 200 includes a processing platform 210, a platform rotating motor 220 and a rail module 230.

The processing platform 210 is utilized to carry the boule 100 to be processed. For example, the processing platform 210 includes a magnet (such as a permanent magnet or an electromagnet), and is able to absorb magnetic objects attached to the boule 100. In some embodiments, the diameter of the boule 100 is 250 mm. In some embodiments, the diameter of the processing platform 210 is 300 mm.

The platform rotating motor 220 is configured to rotate the processing platform 210 along the first rotational axis parallel to the z-axis. In some embodiments, the platform rotating motor 220 stops rotating during the formation of the flat 100F.

The rail module 230 is configured to move the processing platform 210 and the platform rotating motor 220 along the x-axis. In some embodiments, in addition to allowing the processing platform 210 and the platform rotating motor 220 to move on the x-axis, the rail module 230 also allows the processing platform 210 and the platform rotating motor 220 to move along the y-axis.

The rail module 230 enables the processing platform 210 and the platform rotating motor 220 to move between the first processing station and the second processing station. In FIG. 6A and FIG. 6B, the processing platform 210 is moved to the first processing station, so that the boule 100 on the processing platform 210 is able to be processed by the first grinding module 300 in the first processing station.

The first grinding module 300 includes a vertical main axis 315, a first grinding wheel 310, a first servo motor 320 and a first lifting module 330. The first grinding wheel 310 is connected to the vertical main axis 315, and the first servo motor 320 is configured to rotate the first grinding wheel 310 and the vertical main axis 315 along a second rotational axis parallel to the z-axis.

The first lifting module 330 is configured to move the first servo motor 320, the vertical main axis 315 and the first grinding wheel 310 up and down along the z-axis.

In some embodiments, the diameter of the first grinding wheel 310 is 150 mm. In some embodiments, the rotation speed of the first servo motor 320 and the first grinding wheel 310 is 3000 rpm to 6000 rpm.

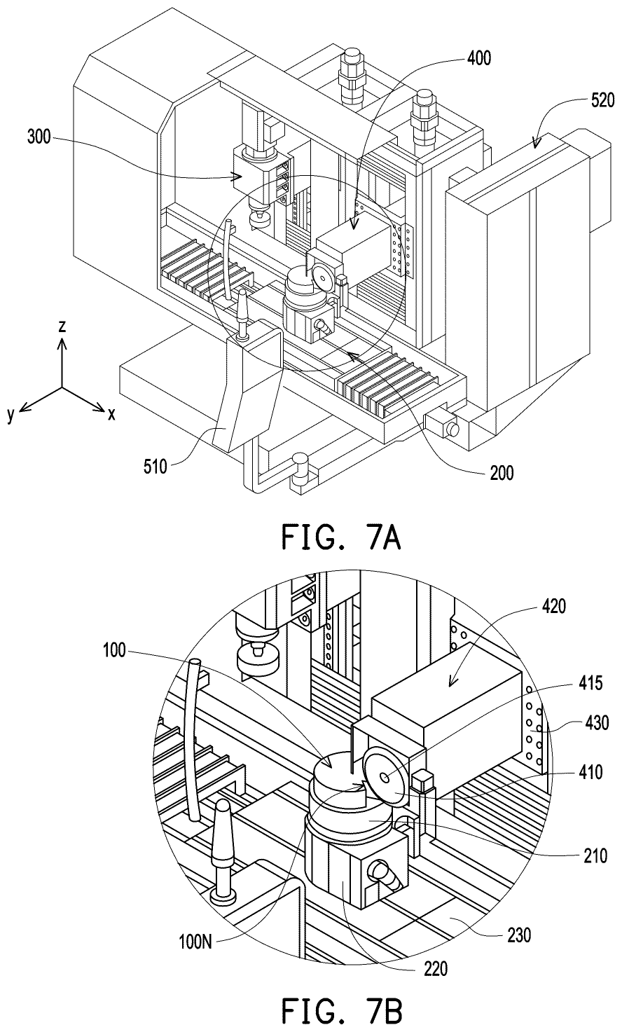

FIG. 7A is a schematic diagram of a grinding equipment and a method of using the grinding equipment to form a notch on the sidewall of a boule according to an embodiment of the present invention. FIG. 7B is a partial enlarged view of FIG. 7A. In this embodiment, no flat is formed on the sidewall of the boule 100. Instead, the boule 100 is moved to the second processing station, and the second grinding module 400 is utilized to form a V-shaped notch 100N on the sidewall of the boule 100.

The second grinding module 400 includes a horizontal main axis 415, a second grinding wheel 410, a second servo motor 420 and a second lifting module 430. The second grinding wheel 410 is connected to the horizontal main axis 415, and the second servo motor 420 is configured to rotate the second grinding wheel 410 and the horizontal main axis 415 along the third rotational axis parallel to the y-axis.

The second lifting module 430 is configured to move the second servo motor 420, the horizontal main axis 415 and the second grinding wheel 410 up and down along the z-axis.

In some embodiments, the diameter of the second grinding wheel 410 is 180 mm. In some embodiments, the rotation speed of the second servo motor 420 and the second grinding wheel 410 is 3000 rpm to 6000 rpm.

Table 1 provides the crack conditions of the boules of Comparative Example 1 to Comparative Example 2 and Example 1 to Example 10 after grinding. In Comparative Examples 1 to 2, the second rotational axis of the first grinding wheel for grinding the sidewall of the boule is perpendicular to the first rotational axis of the boule, and the third rotational axis of the second grinding wheel utilized to grind the top and bottom surfaces of the boule is parallel to the first rotational axis of the boule. In Examples 1 to 10, the second rotational axis of the first grinding wheel for grinding the sidewall of the boule is parallel to the first rotational axis of the boule, and the third rotational axis of the second grinding wheel for grinding the top and bottom surfaces of the boule is perpendicular to the first rotational axis of the boule.

TABLE 1

| | Grinding sidewall of boule | | | | Grinding top surface and bottom surface of boule | | | | |
|---|---|---|---|---|---|---|---|---|---|
| | Rotational | Rotation | | | Rotational | Rotation | | | |
| | axis of | speed | | | axis of | speed | | | |
| | grinding | (rpm) of | | Feed | grinding | (rpm) of | | Feed | |
| | wheel and | grinding | Feed rate | amount | wheel and | grinding | Feed rate | amount | Crack |
| | boule | wheel | (mm/min) | (μm) | boule | wheel | (mm/min) | (μm) | condition |
| Comparative | Perpendicular | 3000 | 50 | 5 | Parallel | 3000 | 50 | 5 | Failure |
| Example 1 | to each other | | | | | | | | rate of |
| | | | | | | | | | cracked |
| | | | | | | | | | ingots > |
| | | | | | | | | | 50% |
| Comparative | Perpendicular | 6000 | 1000 | 500 | Parallel | 6000 | 1000 | 500 | Failure |
| Example 2 | to each other | | | | | | | | rate of |
| | | | | | | | | | cracked |
| | | | | | | | | | ingots > |
| | | | | | | | | | 50% |
| Example 1 | Parallel | 3000 | 100 | 10 | Perpendicular | 3000 | 100 | 10 | No cracks |
| | | | | | to each other | | | | |
| Example 2 | Parallel | 3200 | 150 | 90 | Perpendicular | 3500 | 200 | 70 | No cracks |
| | | | | | to each other | | | | |
| Example 3 | Parallel | 3800 | 220 | 150 | Perpendicular | 3500 | 300 | 100 | No cracks |
| | | | | | to each other | | | | |
| Example 4 | Parallel | 4000 | 340 | 180 | Perpendicular | 3800 | 400 | 150 | No cracks |
| | | | | | to each other | | | | |
| Example 5 | Parallel | 4300 | 460 | 210 | Perpendicular | 4000 | 500 | 200 | No cracks |
| | | | | | to each other | | | | |
| Example 6 | Parallel | 4600 | 530 | 240 | Perpendicular | 4500 | 600 | 250 | No cracks |
| | | | | | to each other | | | | |
| Example 7 | Parallel | 4900 | 610 | 300 | Perpendicular | 4800 | 700 | 300 | No cracks |
| | | | | | to each other | | | | |
| Example 8 | Parallel | 5100 | 780 | 360 | Perpendicular | 5000 | 800 | 350 | No cracks |
| | | | | | to each other | | | | |
| Example 9 | Parallel | 5600 | 950 | 450 | Perpendicular | 5500 | 900 | 400 | No cracks |
| | | | | | to each other | | | | |
| Example 10 | Parallel | 6000 | 1000 | 500 | Perpendicular | 6000 | 1000 | 500 | No cracks |
| | | | | | to each other | | | | |

As can be seen from Table 1, in the embodiment of the present invention, the second rotational axis 310R of the first grinding wheel 310 is parallel to the first rotational axis 200R of the boule 100 (please refer to FIG. 2A), and the third rotational axis 410R of the second grinding wheel 410 is perpendicular to the first rotational axis 200R of the boule 100 (please refer to FIG. 2B), which may improve the probability of cracks in the boule 100 after grinding. The rotation speed of the first grinding wheel 310 and the second grinding wheel 410 is preferably in the range of 3000 rpm to 6000 rpm. When grinding the sidewall of the boule with the first grinding wheel 310, the feed rate is preferably in the range of 100 mm/min to 1000 mm/min, and the feed amount is preferably in the range of 10 μm to 500 μm. On the other hand, when grinding the top or bottom 5 surface of the boule with the first grinding wheel 310, the feed rate is preferably in the range of 100 mm/min to 1000 mm/min, and the feed amount is preferably in the range of 10 μm to 500 μm. Through this grinding method, it is possible to effectively prevent cracks from being generated in the boule 100 after grinding.

In summary, using the grinding equipment of the present invention to grind boule may overcome the problem of cracks in boule during the grinding process and improve the processing efficiency of boule.

What is claimed is:

1. A processing method for a boule, comprising:
moving the boule to a first processing station of a grinding equipment, and utilizing a first grinding wheel located within the first processing station to perform a sidewall grinding process on a sidewall of the boule, wherein during the sidewall grinding process, the boule rotates along a first rotational axis, and the first grinding wheel rotates along a second rotational axis, wherein the first rotational axis is parallel to the second rotational axis, and a direction in which the boule rotates along the first rotational axis is equal to a direction in which the first grinding wheel rotates along the second rotational axis; and
moving the boule to a second processing station of the grinding equipment, and utilizing a second grinding wheel located within the second processing station to perform a top surface grinding process on a top surface of the boule, wherein during the top surface grinding process, the second grinding wheel rotates along a third rotational axis, and the boule rotates along the first rotational axis, wherein the third rotational axis is perpendicular to the first rotational axis.

2. The processing method according to claim 1, further comprising:
after performing the sidewall grinding process and before performing the top surface grinding process, an X-ray instrument is utilized to perform a crystal plane measurement procedure on the boule, and a processing region on the sidewall of the boule is obtained.

3. The processing method according to claim 2, further comprising:
after performing the sidewall grinding process, the first grinding wheel is utilized to form a flat on the processing region.

4. The processing method according claim 2, further comprising:
after performing the sidewall grinding process, the second grinding wheel is utilized to form a V-shaped notch on the processing region.

5. The processing method according to claim 1, wherein during the sidewall grinding process, the first grinding wheel moves along a z-axis, and the boule moves toward the first grinding wheel along an x-axis and/or a y-axis perpendicular to the z-axis, wherein the z-axis is parallel to the first rotational axis and the second rotational axis, and the third rotational axis is parallel to the y-axis.

6. The processing method according to claim 1, wherein during the top surface grinding process, the second grinding wheel moves toward the boule along a z-axis, and the boule moves along an x-axis and/or a y-axis perpendicular to the z-axis, wherein the z-axis is parallel to the first rotational axis and the second rotational axis, and the third rotational axis is parallel to the y-axis.

7. A grinding equipment, comprising:
a movable carrier module, comprising:
a processing platform, configured to move between a first processing station and a second processing station; and
a platform rotating motor, configured to rotate the processing platform along a first rotational axis;
a first grinding module, comprising:
a first grinding wheel, located within the first processing station and configured to move up and down along a z-axis and configured to rotate along a second rotational axis, wherein the second rotational axis is parallel to the first rotational axis; and
a second grinding module, comprising:
a second grinding wheel, located within the second processing station and configured to move up and down along the z-axis and configured to rotate along a third rotational axis, wherein the third rotational axis is perpendicular to the first rotational axis.

8. The grinding equipment according to claim 7, wherein the first grinding module further comprises:
a first servo motor;
a vertical main axis, wherein the first grinding wheel is connected to the vertical main axis, and the first servo motor is configured to rotate the first grinding wheel and the vertical main axis along the second rotational axis; and
a first lifting module, configured to move the first servo motor, the vertical main axis and the first grinding wheel up and down along the z-axis.

9. The grinding equipment according to claim 7, wherein the movable carrier module further comprises:
a rail module, configured to move the processing platform along an x-axis perpendicular to the z-axis.

10. The grinding equipment according to claim 7, wherein the processing platform comprises magnets.
